(19) United States
(12) Patent Application Publication
(10) Pub. No.: US 2025/0210450 A1
(43) Pub. Date: Jun. 26, 2025

(54) HEAT DISSIPATION FOR INTEGRATED CIRCUIT PACKAGE

(71) Applicant: Taiwan Semiconductor Manufacturing Company, Ltd., Hsinchu (TW)

(72) Inventors: Chun-Yen Lan, Hsinchu County (TW); Yu-Hsun Wang, Zhubei City (TW); Pu Wang, Hsinchu City (TW); Li-Hui Cheng, New Taipei City (TW); Ying-Ching Shih, Hsinchu City (TW); Yu-Wei Lin, New Taipei (TW)

(21) Appl. No.: 18/603,766

(22) Filed: Mar. 13, 2024

Related U.S. Application Data
(60) Provisional application No. 63/614,239, filed on Dec. 22, 2023.

(51) Int. Cl. H01L 23/42; H01L 23/00; H01L 23/31; H01L 23/498

(52) U.S. Cl. CPC H01L 23/42; H01L 23/3128; H01L 23/49816; H01L 23/49838; H01L 24/32; H01L 2224/32225; H01L 2924/35121

(57) ABSTRACT

A package structure is provided. The package structure includes a substrate, a die bonded to the substrate, a lid disposed over the die and the substrate, and an interface structure sandwiched between the die and the lid and including a first thermal interface material disposed at corners of a top surface of the die, and a second thermal interface material disposed a rest of the top surface of the die. A Young's modulus of the first thermal interface material is smaller than a Young's modulus of the second thermal interface material.

### PRIORITY DATA

This application claims the benefit of U.S. Provisional Application No. 63/614,239, filed Dec. 22, 2023, which is hereby incorporated by reference in its entirety.

### BACKGROUND

In some Three-Dimensional Integrated Circuits (3DIC), device dies are bonded to a package substrate to form a package. The heat generated by the device dies during operation needs to be dissipated to prevent performance degradation or even physical damage. Additionally, the package structure may lack structural strength to avoid warping. To dissipate heat and to increase structural integrity, a metal lid may be bonded the package substrates to engage the device dies.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method 100 for forming a package structure, according to various aspects of the present disclosure.

FIGS. 2-8 illustrates fragmentary cross-sectional view of a work-in-progress structure going through various steps of the method 100 in FIG. 1, according to various aspects of the present disclosure.

FIG. 9 illustrates a flowchart of a method 300 for forming a package structure, according to various aspects of the present disclosure.

FIGS. 10-15 illustrates fragmentary cross-sectional view of a work-in-progress structure going through various steps of the method 100 in FIG. 9, according to various aspects of the present disclosure.

FIG. 16 illustrates a flowchart of a method 400 for forming a package structure, according to various aspects of the present disclosure.

FIGS. 17-21 illustrates fragmentary cross-sectional view of a work-in-progress structure going through various steps of the method 100 in FIG. 16, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Semiconductor packaging technologies were once just considered backend processes that facilitates chips to interface external circuitry. Times have changed. Computing workloads have evolved so much that brought packaging technologies to the forefront of innovation. Modern packaging provides integration of multiple chips or dies into a single semiconductor device. Depending on the level of stacking, modern semiconductor packages can have a 2.5D structure or a 3D structure. In a 2.5D structure, at least two dies are coupled to a redistribution layer (RDL) structure or an interposer that provides chip-to-chip communication. The at least two dies in a 2.5D structure are not stacked one over another vertically. In a 3D structure, at least two dies are stacked one over another and interact with each other by way of through silicon vias (TSVs). Depending on the processes adopted, the 2.5D structure and the 3D structure may have an Integrated Fan-Out (InFO) construction or a Chip-on-Wafer-on-Substrate (CoWoS®) construction. To provide additional structural integrity and to improve heat dissipation, a metal lid or a ring may be attached to the package structure by way of a thermal interface material (TIM) or an adhesive. The TIM plays a role in conducting heat to the metal lid. Both the TIM and the adhesive are designed to absorb stress and prevent crack propagation. Depending on their compositions, the TIM and the adhesive can have different thermal conductivities and stiffnesses. In many instances, TIMs and adhesive with higher thermal conductivities or greater stiff may not absorb stress well.

The present disclosure provides a hybrid arrangement for the thermal interface material (TIM) and the adhesive to achieve high thermal conductivity, high coplanarity and high stress absorption. In some embodiments, a package component is bonded to a front side of a package substrate. The package component may include more than one dies and may include an interposer or a redistribution layer. A first TIM and a second TIM are dispensed over the package component. A lid is placed over the package component and the package substrate to engage the first TIM the second TIM. After the first TIM and the second TIM are cured, solder features are formed over a back side of the package substrate. In some other embodiments, a first TIM and a second TIM are dispensed over the package component and a first adhesive and a second adhesive are disposed over the package substrate. A lid is placed over the die and the substrate to engage the first TIM and the second TIM as well as the first adhesive and the second adhesive. After the first TIM, the second TIM, the first adhesive, and the second adhesive are cured, solder features are formed over a back side of the package substrate.

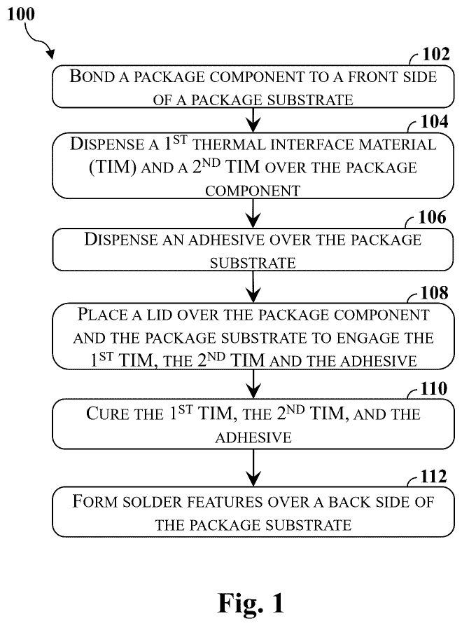

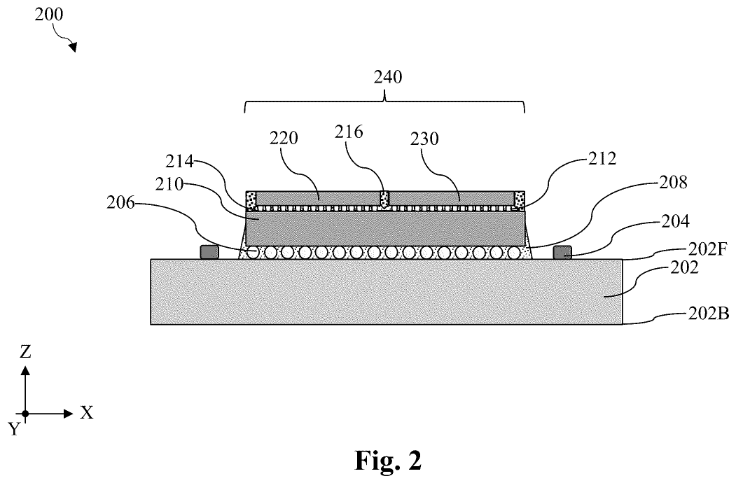

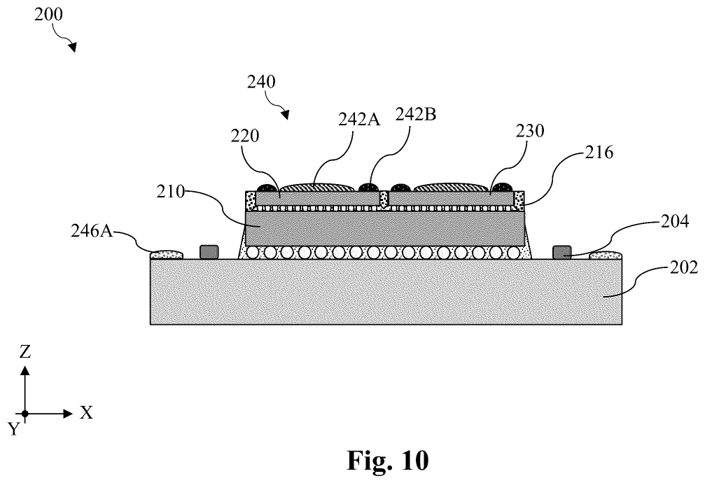

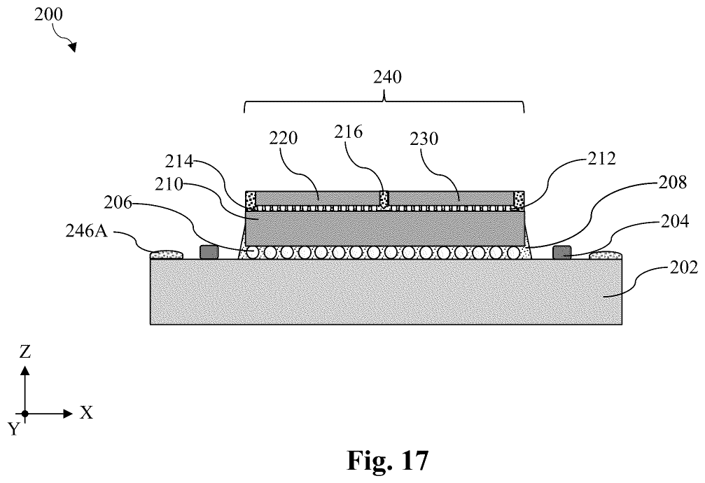

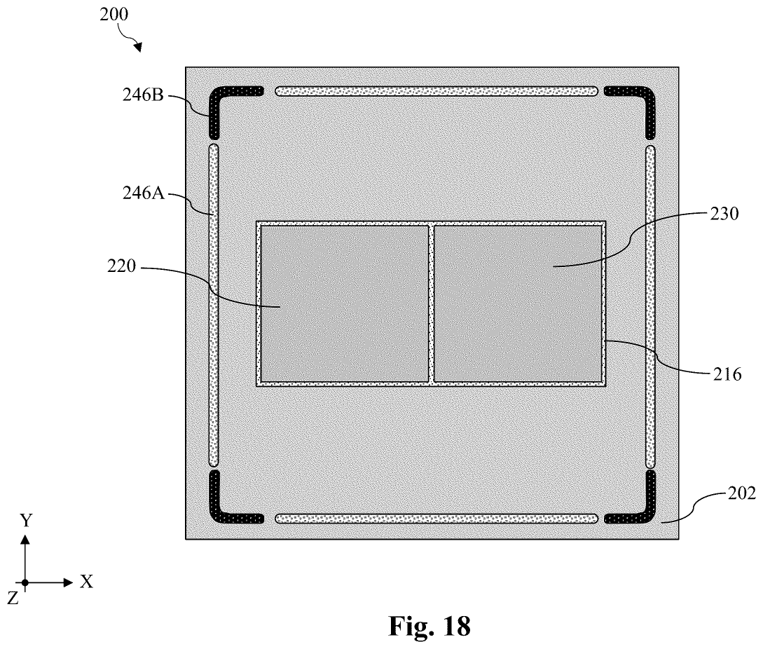

The various aspects of the present disclosure will now be described in more detail with reference to the figures. In that regard, FIGS. 1, 9 and 16 are flowcharts illustrating methods 100, 300 and 400 of forming a package structure on a work-in-progress (WIP) structure 200 (shown in FIGS. 2-8, 10-15 and 17-21), according to various aspects of the present disclosure. Methods 100, 300 and 400 are merely examples and are not intended to limit the present disclosure to what is explicitly illustrated in method 100, 300 or 400. Additional steps can be provided before, during and after method 100, 300 or 400, and some steps described can be replaced, eliminated, or moved around for additional embodiments of the method. Not all steps are described herein in detail for reasons of simplicity. Method 100 is described below in conjunction with FIG. 2-8, which are fragmentary cross-sectional views and top views of the WIP structure 200 at different stages of fabrication according to various embodiments of method 100. Method 300 is described below in conjunction with FIG. 10-15, which are fragmentary cross-sectional or top views of the WIP structure 200 at different stages of fabrication according to various embodiments of method 300. Method 400 is described below in conjunction with FIG. 17-21, which are fragmentary cross-sectional or top views of the WIP structure 200 at different stages of fabrication according to various embodiments of method 400. Because the WIP structure 200 will be fabricated into a package structure, the WIP structure 200 may be referred to herein as a package structure 200 as the context requires. For avoidance of doubts, the X, Y and Z directions in FIGS. 2-8, 10-15, and 17-21 are perpendicular to one another. Throughout the present disclosure, unless expressly otherwise described, like reference numerals denote like features.

Referring to FIGS. 1 and 2, method 100 includes a block 102 where a package component 240 is bonded to a front side surface 202F of a package substrate 202. In some embodiments, the package substrate 202 may include a printed circuit board (PCB) or the like. While not explicitly shown in the features, the package substrate 202 may include through-substrate vias (TSVs) or through hole connectors that extend from the front side surface 202F to the back side surface 202B of the package substrate 202. Additionally, in order to electrically couple to the package component, the package substrate 202 may include a plurality of contact pads over the front side surface 202F. In order to electrically couple to solder features (to be describe below) over the back side surface 202B, the package substrate 202 may also include a plurality of contact pads or under bump metallization (UBM) features over the back side surface 202B. At least one passive component 204 may be bonded on the package substrate 202. The at least one passive component 204 may include a capacitor or a resistor. The package component 240 is a multi-die package (or multi-chip package) that may include more than one device die. A device die may also be referred to as a die or a chip. In the depicted embodiment, the package component 240 includes a first die 220, a second die, and an interposer 210. In some embodiments represented in FIG. 2, the first die 220 and the second die 230 are bonded to the interposer 210 by way of a plurality of micro-bumps 212. The space between the interposer 210 and the first die 220 or between the interposer 210 and the second die 230 may be filled with a first underfill 214. The first die 220 and the second die 230 are disposed side-by-side over the interposer 210. To provide structural integrity and to improve stress absorption, each of the first die 220 and the second die 230 are surrounded by a molding material 216. The molding material 216 may also be referred to as an encapsulation layer 216. The package component 240 further includes a plurality of connection features to interface the package substrate 202. In some embodiments, the plurality of connection features 206 may include controlled collapse chip connection (C4) bumps or other solder bumps. The space between the package component 240 and the front side surface 202F of the package substrate 202 may be filled with a second underfill 208.

The interposer 210 may include a semiconductor material or glass. In one embodiment, the interposer 210 includes silicon (Si). In some alternative embodiments, the interposer 210 includes silicon germanium (SiGe) or silicon carbon (SiC). Each of the first die 220 and the second die 230 may be a system-on-chip (SOC) die, a logic die, an application specific integrated circuit (ASIC) die, or other device die. That is, each of the first die 220 and the second die 230 may include a plurality of transistors, such as planar transistors, fin-type field effect transistors (FinFETs), gate-all-around (GAA) transistors, nanowire transistors, nanosheet transistors, or other multi-gate transistors. While the first die 220 and the second die 230 are depicted in FIG. 2 as having the same dimensions along the X-Y plane, they may have different dimension along the X-Y plane. The first underfill 214 may include polymer or epoxy. The molding material 216 may include a base material and fillers embedded in the base material. In some implementations, the base material of the molding material 216 may include polymer, resin or epoxy and the fillers may include spherical particles of silicon oxide (silica), zinc oxide or aluminum oxide.

At block 102, the package component 240 is placed over the package structure 202 such that the connection features 206 are vertically aligned with the contact pads on the front side surface 202F of the package substrate 202. A reflow process is performed such that the connection features 206 electrically couple the interposer 210 of the package component 240 to the package substrate 202. After the reflow process, a liquid precursor of the second underfill 208 is allowed to fill the gap between the interposer 210 and the front side surface 202F of the package substrate 202 through capillary action. The liquid precursor is then cured by annealing to a curing temperature to form the second underfill 208. In some embodiments represented in FIG. 2, a portion of the second underfill 208 may extend along sidewalls of the package component 240.

The package substrate 202 and the package component 240 shown in FIG. 2 may be collectively referred to as a work-in-progress (WIP) structure 200. During operations at various blocks of method 100, components may be added to the WIP structure 200 and the present disclosure will continue to refer to the resulting structure as the WIP structure 200.

Referring to FIGS. 1 and 3-5, method 100 includes a block 104 where a first thermal interface material (TIM) 242A and a second TIM 242B are dispensed over the package component 240. For purpose of the present disclosure, TIM refers to materials that are placed between an electronic device and a heat sink to improve heat dissipation of the electronic device. Because voids and gaps introduce air in the heat conduction path and air has low thermal conductivity, one of TIM's functions is to fill the gaps between the electronic device and the heat sink so as to reduce voids and gaps. To serve the gap filling function well, TIM or a precursor of TIM should possess reasonable flowability or flexibility. Additionally, TIM should have sufficient thermal conductivity to facilitate heat conduction. Furthermore, it is desirable that TIM has good stress absorption property to protect the electric device and prevent delamination. According to the present disclosure, TIM may be applied in a liquid form or as a pre-cut tape. No matter what types of TIM are used, a tradeoff between thermal conductivity and stress absorption ability is present. It has been observed that TIM with higher thermal conductivity tends to be rigid or stiff, which tends to result in less stress absorption quality. Conversely, flexible TIM tends to have satisfactory stress absorption properties but is less likely to conduct heat well.

It has been observed through experimentation, simulation and field data that stress tends to concentrate at corners of a rectangular die. When the TIM lacks flexibility, the concentration of stress may initiate a crack in the TIM. The crack may propagate into the molding material 216 and the first underfill 214 to cause delamination of the first die 220 or the second die 230. According to the present disclosure, two types of TIM—a first TIM 242A and a second TIM 242B are dispensed or applied at block 104. The first TIM 242A and the second TIM 242B have different properties. The first TIM 242A serves as a primary heat conducting medium and includes a thermal conductivity greater than a thermal conductivity of the second TIM 242B. The second TIM 242B serves as a primary stress absorber and includes a Young's modulus smaller than a Young's modulus of the first TIM 242A.

The first TIM 242A may be applied as a tape or dispensed as a liquid. When the first TIM 242A is a tape, the first TIM 242A may include metal (i.e., copper or aluminum), graphite, or graphene. When the first TIM 242A is dispensed as a liquid, the first TIM 242A may include a base material and a thermal conductive filler. In some instances, the base material for the first TIM 242A may include resin or epoxy and the thermal conductive filler for the first TIM 242A may include metal oxide (e.g., aluminum oxide, zinc oxide), aluminum nitride, hexagonal boron nitride, metal (i.e., copper, silver or aluminum), diamond, graphene, or graphite. The second TIM 242B is dispensed as a liquid and may include a flexible base material and a thermal conductive filler. For avoidance of doubt, a Young's modulus of the flexible base material is smaller than a Young's modulus of the base material of the first TIM 242A. In some implementations, the flexible base material of the second TIM 242B may include silicone. The thermal conductive filler in the second TIM 242B may include metal oxide (e.g., aluminum oxide, zinc oxide), aluminum nitride, hexagonal boron nitride, metal (i.e., copper, silver or aluminum), diamond, graphene, or graphite. When both the first TIM 242A and the second TIM 242B are dispensed a liquid, a filler content (or filler concentration) in the first TIM 242A is greater than a filler content in the second TIM 242B. Because the second TIM 242B is still in the heat conduction path, it is desirable for the second TIM 242B to have high thermal conductivity. That said, because a higher filler content may lead to loss of stress absorption ability, the filler content in second TIM 242B needs to be lower than that in the first TIM 242A to maintain sufficient stress absorption ability. In some instances, the second TIM 242B may have a Young's modulus smaller than 1 MPa (megapascal).

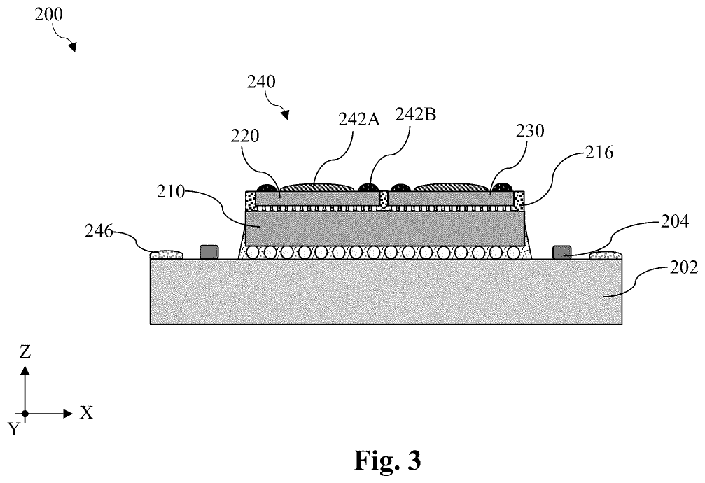

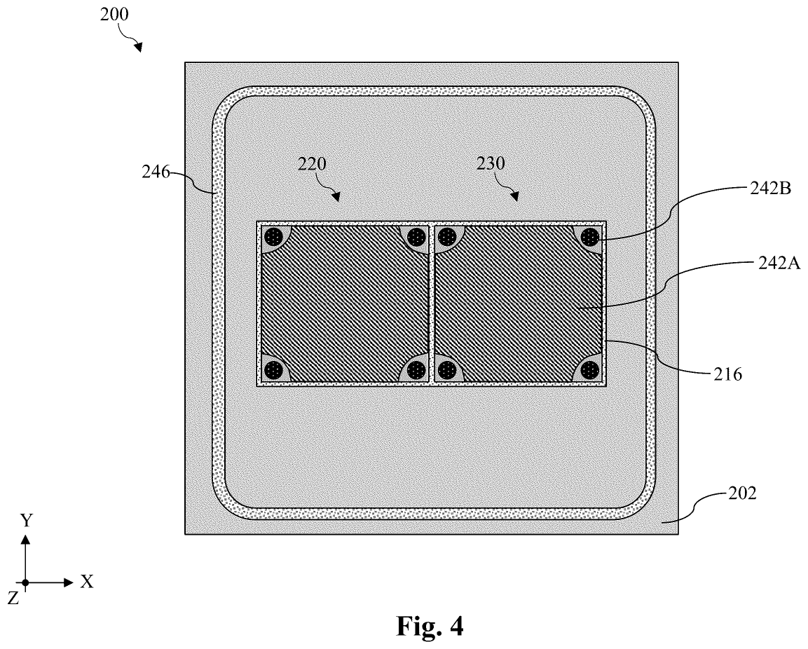

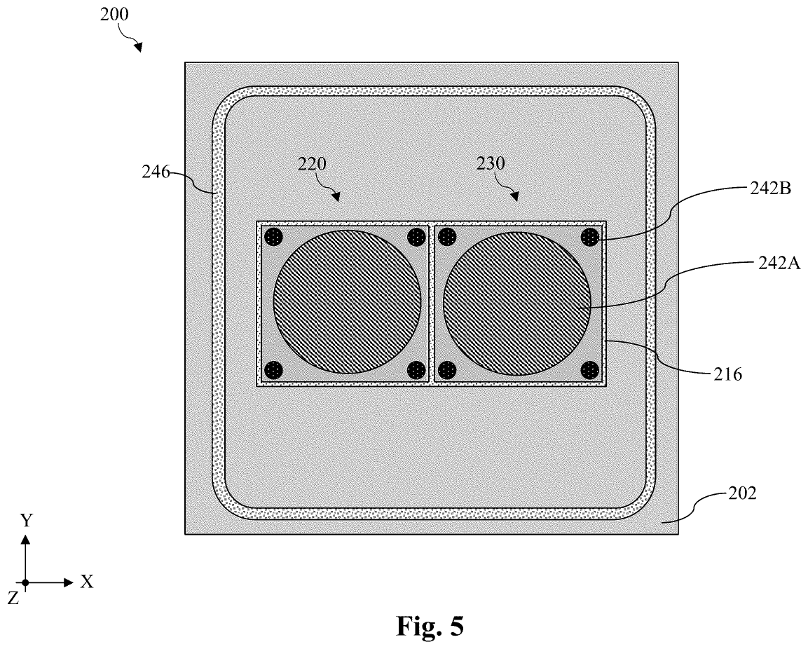

Reference is now made to FIGS. 3-5. Each of the first die 220 and the second die 230 includes a rectangular shape in a top view. In some embodiments, each of the first die 220 and the second die 230 has a length and a width between about 30 mm and about 50 mm. In some embodiments represented in FIGS. 3-5, the second TIM 242B is dispensed at or around four (4) corners of each of the first die 220 and the second die 230. At an interface between the first die 220 and the second die 230, the second TIM 242B may span from one corner of the first die 220, over the molding material 216, and to one corner of the second die 230. In some embodiments represented in FIG. 4, the first TIM 242A is applied as a pre-cut tape while the second TIM 242B is dispensed as a liquid (or gel, paste, grease) using a precision dispensing system. In some alternative embodiments represented in FIG. 5, both the first TIM 242A and the second TIM 242B are dispensed as a liquid (or gel, paste, grease) using a prevision dispensing system. As shown in FIGS. 4 and 5, the second TIM 242B drops are disposed at each of the four (4) corners of the first die 220 and the second die 230 while the first TIM 242A tapes or drops are attached to the non-corner regions of the first die 220 and the second die 230. In embodiments represented in FIGS. 4 and 5, the dispensed second TIM 242B drops are spaced apart from the first TIM 242A pre-cut tapes or drops. In some alternative embodiments not explicitly shown in the figures, the dispensed second TIM 242B drops are in contact with the first TIM 242A pre-cut tapes or drops.

Referring to FIGS. 1 and 3-5, method 100 includes a block 106 where an adhesive 246 is dispensed over the package substrate 202. The adhesive 246 functions to attach a lid 250 (to be described below) to the package substrate 202. Because heat is generated by the package component 240, not the package substrate 202, the adhesive 246 does not play a meaningful role in dissipation of heat. For that reason, it is more important for the adhesive 246 to possess stress absorption properties than to have good thermal conductivity. In some implementations, the adhesive 246 may include a base material and a structural filler. In some instances, the base material for the adhesive 246 may include silicone, nylon, polyetheretherketone (PEEK), epoxy, or resin and the structural filler of the adhesive 246 may include silica, zinc oxide, aluminum oxide, silver, or aluminum. It has been observed that a Young's modulus of the adhesive 246 increases with a content of the structural filler in the adhesive 246. When the adhesive 246 has a low structural filler content (or low structural filler concentration) and a low Young's modulus, the elasticity of the adhesive 246 allows the adhesive 246 to absorb stress better. When the adhesive 246 has a high structural filler content and a high Young's modulus, the rigidity of the adhesive 246 helps maintain a coplanarity of a lid 250 or a ring 270 (to be described below). In the depicted embodiments, the adhesive 246 is dispensed as a liquid (or gel, paste, grease) using a precision dispensing system.

Referring to FIGS. 1 and 6-7, method 100 includes a block 108 where a lid 250 is placed over the package component 240 and the package substrate 202 to engage the first TIM 242A, the second TIM 242B, and the adhesive 246. In some embodiments, the lid 250 may be formed of a metal or an alloy, such as aluminum (Al), copper (Cu), iron (Fe), nickel (Ni), cobalt (Co), or an alloy thereof. Example alloys may include an aluminum-copper alloy, an iron-nickel alloy, or an iron-nickel-cobalt alloy. Because the lid 250 is formed of a metal or a metal alloy, it may be referred to as a metal lid. The lid 250 has at least three functions. First, it serves as a heat sink to dissipate heat from the package component 240 by way of the first TIM 242A and the second TIM 242B. Second, it provides structural rigidity to the package substrate 202 to prevent or reduce warping. Third, it creates a sealed environment to protect the package component 240. At block 108, the lid 250 is placed over the package component 240 and the package substrate 202 such that its bottom edges engage the adhesive 246 and its backside surface presses on and engages the first TIM 242A and the second TIM 242B.

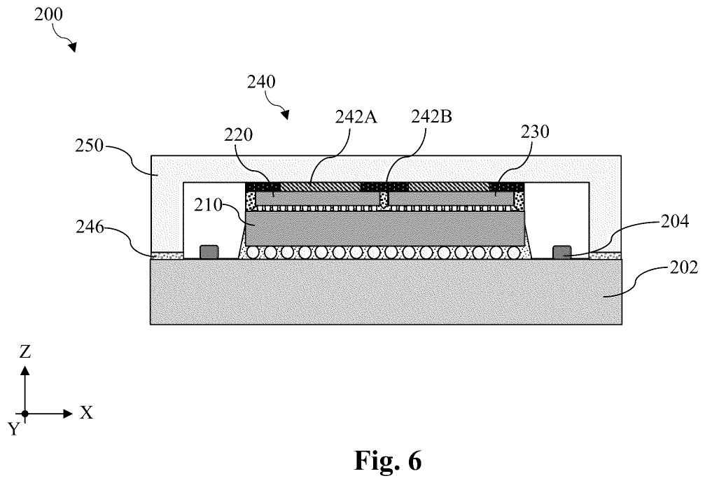

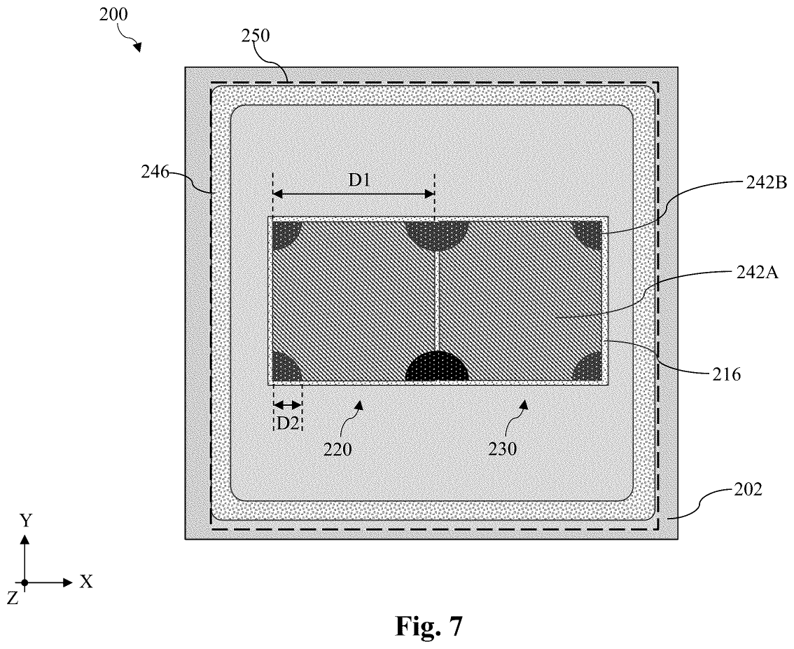

As representatively shown in FIGS. 6-7, when the first TIM 242A and the second TIM 242B are dispensed as a liquid, the lid 250 presses the first TIM 242A and the second TIM 242B to spread the same to cover a larger surface of the package component 240. In some embodiments represented in the figures, the first TIM 242A and the second TIM 242B merge without any voids or gaps at the interface between the first TIM 242A and the second TIM 242B. When the first TIM 242A is applied as a pre-cut tape, the first TIM 242A serves as a spacer to define the thickness of the first TIM 242A and the second TIM 242B between the package component 240 and the backside surface of the lid 250. In some embodiments represented in FIG. 7, after the placement of the lid 250, the second TIM 242B and the adhesive 246 are spread out because the lid 250 is pressed onto the package component 240 and the package substrate 202 at block 108. When the first TIM 242A is dispensed as a liquid (or gel, paste, grease), the first TIM 242A also spreads due to the placement of the lid 250. In some embodiments represented in FIG. 7, the spread-out second TIM 242B may span over and be in contact with the molding material 216.

Referring to FIGS. 1 and 6-7, method 100 includes a block 110 where the first TIM 242A, the second TIM 242B, and the adhesive 246 are cured. In some embodiments, the first TIM 242A (when dispensed as a liquid), the second TIM 242B, and the adhesive 246 are thermally curable. In these embodiments, the WIP structure 200 shown in FIG. 6 may be subject to an anneal process to cure the first TIM 242A (when dispensed as a liquid), the second TIM 242B, and the adhesive 246. In some embodiments, the anneal process for curing the first TIM 242A (when dispensed as a liquid), the second TIM 242B, and the adhesive 246 may be between about 130° C. and about 180° C. This temperature range is not trivial. When the annealing temperature is smaller than 130° C., the curing process may be prolonged or the curing may be incomplete. When the annealing temperature is greater than 180° C., thermal damages may be more likely. Reference is made to FIG. 7. An edge of each of the first die 220 and the second die 230 may have a first dimension D1. After the first TIM 242A and the second TIM 242B are cured, the cured second TIM 242B may have a second dimension D2 along an edge of the first die 220 or the second die 230. In some embodiments, the first dimension D1 may be between about 30 mm and about 50 mm and the second dimension D2 may be between about 2 mm and about 4 mm. A ratio of the second dimension D2 to the first dimension D1 may be between about 0.04 and about 0.13, or between about 4% and about 13.3%. Because the second TIM 242B occupies two corners along an edge, the second TIM 242B may engage about 8% to about 26.6% each edge of the first die 220 and the second die 230. These dimensions or ratios are selected to ensure sufficient second TIM 242B at the corners to absorb stress while the low Young's modulus of the TIM 242B does not impact the structural integrity of the package.

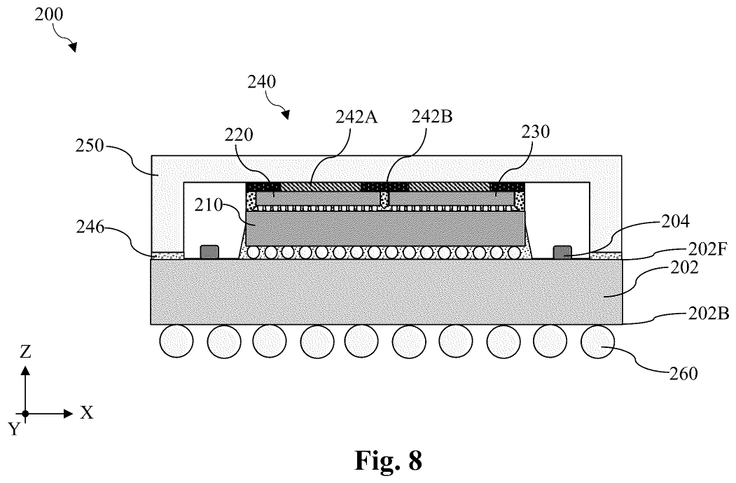

Referring to FIGS. 1 and 8, method 100 includes a block 112 where solder features 260 are formed over a back side of the package substrate 202. As described above, the package substrate 202 may also include a plurality of contact pads or under bump metallization (UBM) features over the back side surface 202B. At block 112, solder features 260 are formed over the plurality of contact pads tor UBM features. In some embodiments, the solder features 260 may include alloys of tin, lead, silver, copper, nickel, bismuth, or combinations thereof.

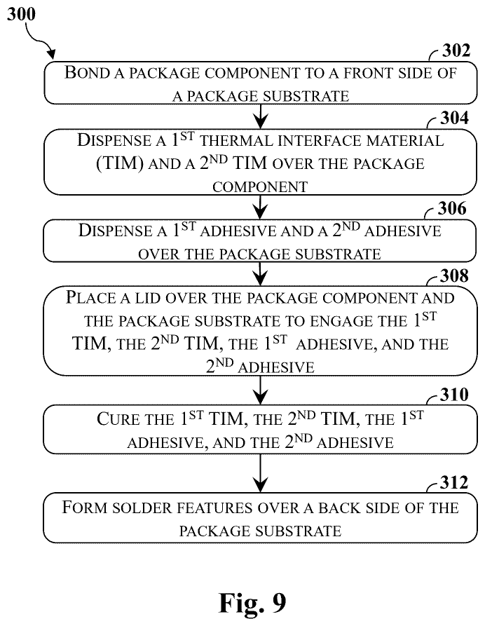

In method 100 described above, a first TIM 242A and a second TIM 242B are dispensed or applied to a top surface of a package component 240 while one type of adhesive 246 is used to attach a lid 250 to a front side surface 202F of the package substrate 202. Particularly, the second TIM 242B is dispensed at corners of dies of the package component 240 and the first TIM 242A is applied or dispenses at non-corner areas of the dies of the package component 240. A Young's modulus of the second TIM 242B is smaller than a Young's modulus of the first TIM 242A such that the second TIM 242B has a better stress absorption ability. The first TIM 242A is to thermally conductive than the second TIM 242B to better dissipate heat to the lid 250. Method 300 shown in FIG. 9 is different from method 100 in at least that two types of adhesive are used to attach the lid 250 to the package substrate 202.

Referring to FIGS. 9 and 2, method 300 includes a block 302 where a package component 240 is bonded to a front side surface 202F of a package substrate 202. Operations at block 302 are substantially similar to those at block 102 of method 100 described above. For that reason, details of operations at block 302, the package component 240, and the package substrate 202 are omitted for brevity.

Referring to FIGS. 9 and 10-12, method 300 includes a block 304 where a first TIM 242A and a second TIM 242B are dispensed over the package component 240. Operations at block 304 are substantially similar to those at block 104 of method 100 described above. For that reason, details of operations at block 304, the first TIM 242A, and the second TIM 242B are omitted for brevity.

Referring to FIGS. 9 and 10-12, method 300 includes a block 306 where a first adhesive 246A and a second adhesive 246B are dispensed over the package substrate 202. Both the first adhesive 246A and the second adhesive 246B function to attach a lid 250 (to be described below) to the package substrate 202. Because heat is generated by the package component 240, not the package substrate 202, the first adhesive 246A and the second adhesive 246B do not play a meaningful role in dissipation of heat. For that reason, it is more important for the first adhesive 246A and the second adhesive 246B to possess stress absorption properties than to have good thermal conductivity. Both the first adhesive 246A and the second adhesive 246B may include a base material and a structural filler. The base material determines a baseline Young's modulus and the structural filler functions to increase the rigidity. It has been observed that stress tends to concentrate at four (4) corners of the lid 250 (to be described below) that requires an adhesive that has low Young's modulus. It has also been observed that rigidity is needed in the adhesive in order to provide coplanarity of the lid 250. At block 306, the first adhesive 246A and the second adhesive 246B are different to provide different stress absorption properties. In one embodiment, both the first adhesive 246A and the second adhesive 246B include the same base material and the same structural filler. The first adhesive 246A and the second adhesive 246B are different in terms of structural filler contents. The base material may include silicone, nylon, polyetheretherketone (PEEK), epoxy, or resin and the structural filler may include silica, aluminum oxide, zinc oxide, silver, or aluminum. In this embodiment, the first adhesive 246A has a first structural filler content between about 70% and about 90% and the second adhesive 246B as a second structural filler content between about 30% and about 70%. The first structural filler content falls in a range that is generally deemed in the industry as sufficient to provide adequate mechanical strength. The second structural filler content may be considered in the industry as not having enough filler to provide sufficient mechanical strength.

In another embodiment, the first adhesive 246A and the second adhesive 246B may share the same structural filler but have different base materials. A first adhesive 246A includes a first base material and a second adhesive 246B includes a second base material. A Young's modulus of the second base material is smaller than a Young's modulus of the first base material. In some instances, the first base material of first adhesive 246A includes epoxy and resin and the second base material of the second adhesive 246B includes silicone. With a smaller Young's modulus, the second base material allows the second adhesive to be more elastic and possess better stress absorption abilities. With a greater Young's modulus, the first base material makes the first adhesive 246A rigid to provide a better coplanarity of a lid 250.

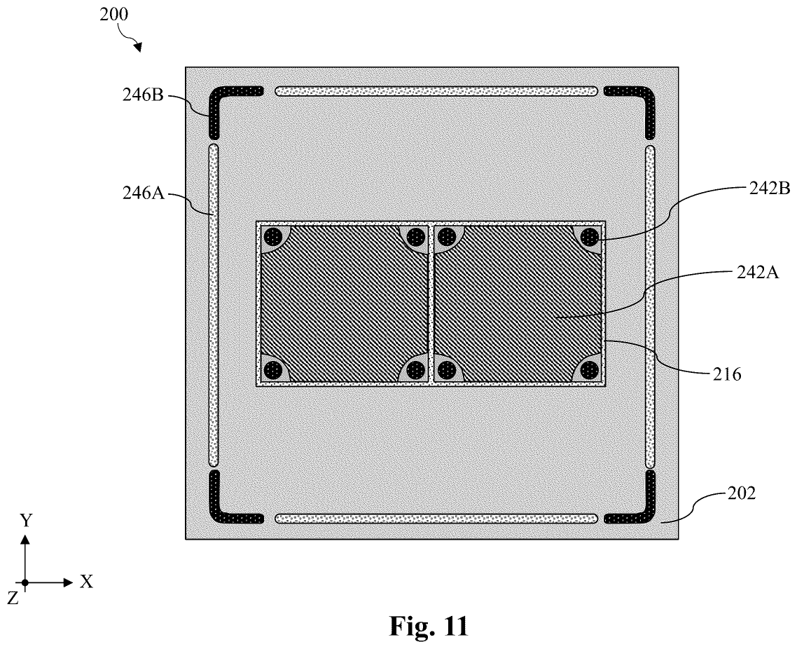

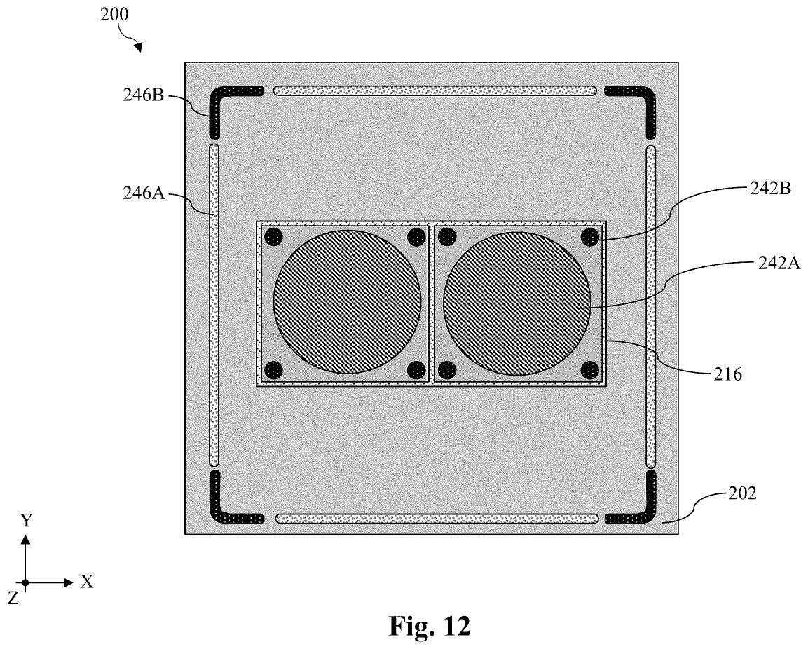

At block 306, the first adhesive 246A and the second adhesive 246B are dispensed as a liquid (or gel, paste, or grease). As shown in FIGS. 11 and 12, the first adhesive 246A is dispensed over the landing areas of four (4) bottom edges of the lid 250 and the second adhesive 246B is dispensed over the landing areas of four (4) corners of the lid 250.

Referring to FIGS. 9 and 13-14, method 300 includes a block 308 where a lid 250 is placed over the package component 240 and the package substrate 202 to engage the first TIM 242A, the second TIM 242B, the first adhesive 246A, and the second adhesive 246B. In some embodiments, the lid 250 may be formed of a metal or an alloy, such as aluminum (Al), copper (Cu), iron (Fe), nickel (Ni), cobalt (Co), or an alloy thereof. Example alloys may include an aluminum-copper alloy, an iron-nickel alloy, or an iron-nickel-cobalt alloy. Because the lid 250 is formed of a metal or a metal alloy, it may be referred to as a metal lid. At block 308, the lid 250 is placed over the package component 240 and the package substrate 202 such that its bottom edges engage the first adhesive 246A and the second adhesive 246B and its backside surface presses on and engages the first TIM 242A and the second TIM 242B.

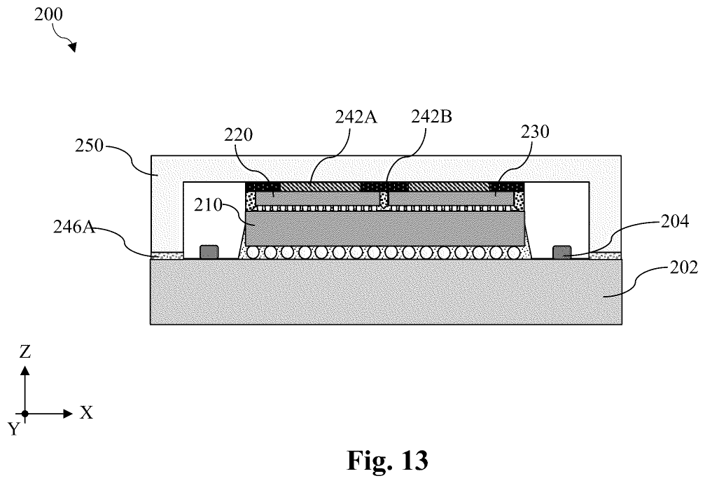

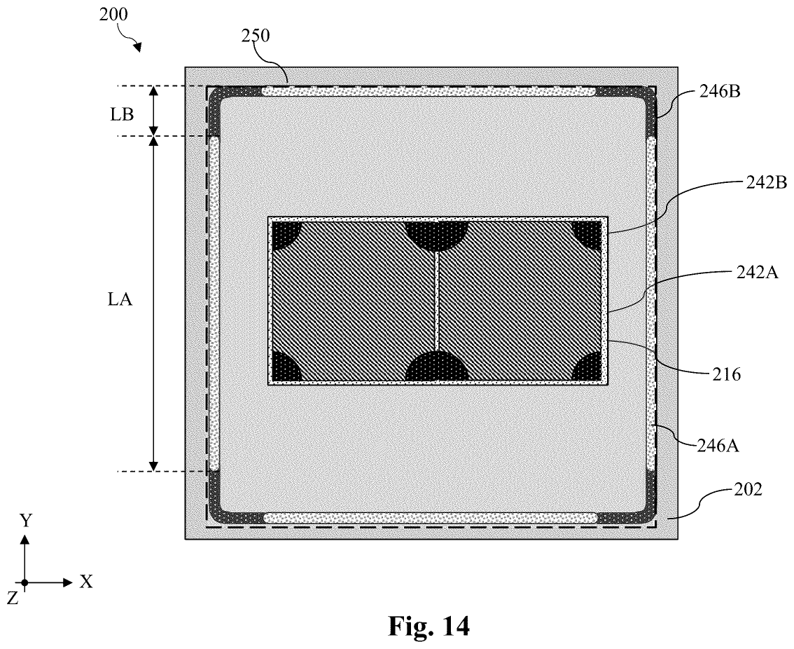

As representatively shown in FIGS. 13-14, the lid 250 presses the first TIM 242A and the second TIM 242B to spread the same to cover a larger surface of the package component 240. In the depicted embodiments, the first TIM 242A and the second TIM 242B merge without any voids or gaps at the interface between the first TIM 242A and the second TIM 242B. In some embodiments represented in FIG. 14, the spread-out second TIM 242B may span over and be in contact with the molding material 216. Similarly, the lid 250 presses the first adhesive 246A and the second adhesive 246B against the package substrate 202 to spread them over a larger area of the package substrate 202. In some embodiments represented in the figures, the first adhesive 246A and the second adhesive 246B merge without any voids or gaps at the interface between the first adhesive 246A and the second adhesive 246B. Reference is made to FIG. 14. The lid 250 assumes a rectangular shape in a top view. Each edge of the lid 250 may a first length LA that engages the first adhesive 246A and a second length LB that engages the second adhesive 246B. In some implementations, the first length LA accounts for between about 70% and about 80% of an edge of the lid 250 while the second length LB accounts for between about 10% and about 15% of an edge of the lid 250. These ratios and percentages are selected to ensure sufficient second adhesive 246B at the corners to absorb stress while the low Young's modulus of the second adhesive 246B does not impact the structural integrity of the package.

Referring to FIGS. 9 and 13-14, method 300 includes a block 310 where the first TIM 242A, the second TIM 242B, the first adhesive 246A, and the second adhesive 246B are cured. In some embodiments, the first TIM 242A, the second TIM 242B, the first adhesive 246A, and the second adhesive 246B are thermally curable. In these embodiments, the WIP structure 200 shown in FIG. 13 may be subject to an anneal process to cure the first TIM 242A (when dispensed as a liquid), the second TIM 242B, the first adhesive 246A, and the second adhesive 246B. In some embodiments, the anneal process for curing the first TIM 242A (when dispensed as a liquid), the second TIM 242B, the first adhesive 246A, and the second adhesive 246B may be between about 130° C. and about 180° C. Reference is made to FIG. 14. The lid 250 assumes a rectangular shape in a top view. Each edge of the lid 250 may a first length LA that engages the first adhesive 246A and a second length LB that engages the second adhesive 246B. In some implementations, the first length LA accounts for between about 70% and about 80% of an edge of the lid 250 while the second length LB accounts for between about 10% and about 15% of an edge of the lid 250.

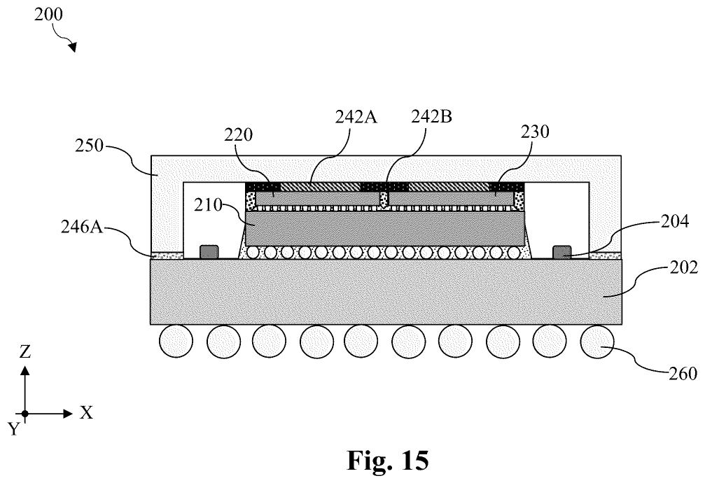

Referring to FIGS. 9 and 15, method 300 includes a block 312 where solder features 260 are formed over a back side of the package substrate 202. Operations at block 312 are substantially similar to those at block 112 of method 100 described above. For that reason, details of operations at block 312 and the solder features 260 are omitted for brevity.

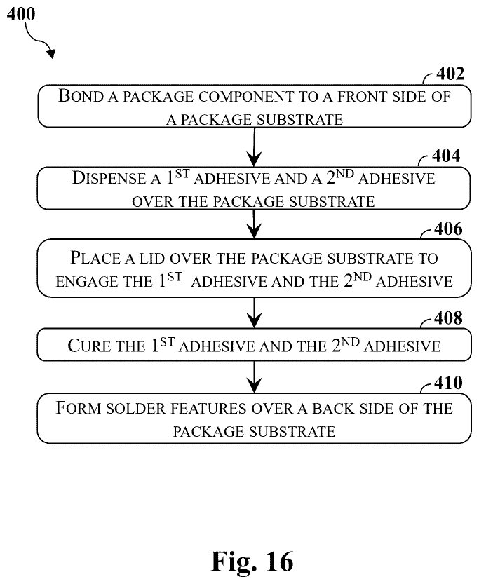

In methods 100 and 300 described above, a first TIM 242A and a second TIM 242B are dispensed or applied to a top surface of a package component 240 to engage a lid 250. Particularly, the second TIM 242B is dispensed at corners of dies of the package component 240 and the first TIM 242A is applied or dispenses at non-corner areas of the dies of the package component 240. A Young's modulus of the second TIM 242B is smaller than a Young's modulus of the first TIM 242A such that the second TIM 242B has a better stress absorption ability. The first TIM 242A is to thermally conductive than the second TIM 242B to better dissipate heat to the lid 250. Method 400 shown in FIG. 16 is different from method 100 or method 300 in at least that a ring 270, rather than a lid 250, is attached to the package substrate 202 using a first adhesive 246A and a second adhesive 246B. Method 400 does not dispense or apply any TIM over the package component 240 because a top surface of the package component is left exposed for air cooling or to interface alternative cooling arrangement.

Referring to FIGS. 16 and 2, method 400 includes a block 402 where a package component 240 is bonded to a front side surface 202F of a package substrate 202. Operations at block 402 are substantially similar to those at block 102 of method 100 described above. For that reason, details of operations at block 402, the package component 240, and the package substrate 202 are omitted for brevity.

Referring to FIGS. 16 and 17-18, method 400 includes a block 404 where a first adhesive 246A and a second adhesive 246B are dispensed over the package substrate 202. Operations at block 404 are substantially similar to those at block 306 of method 300 described above. For that reason, details of operations at block 404 are omitted for brevity.

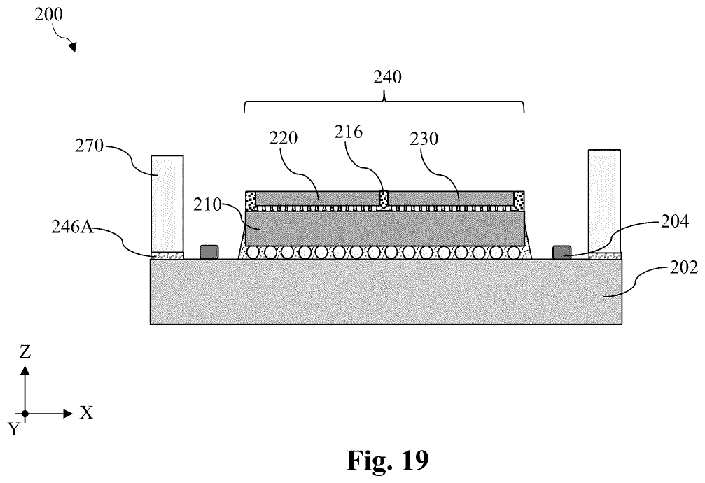

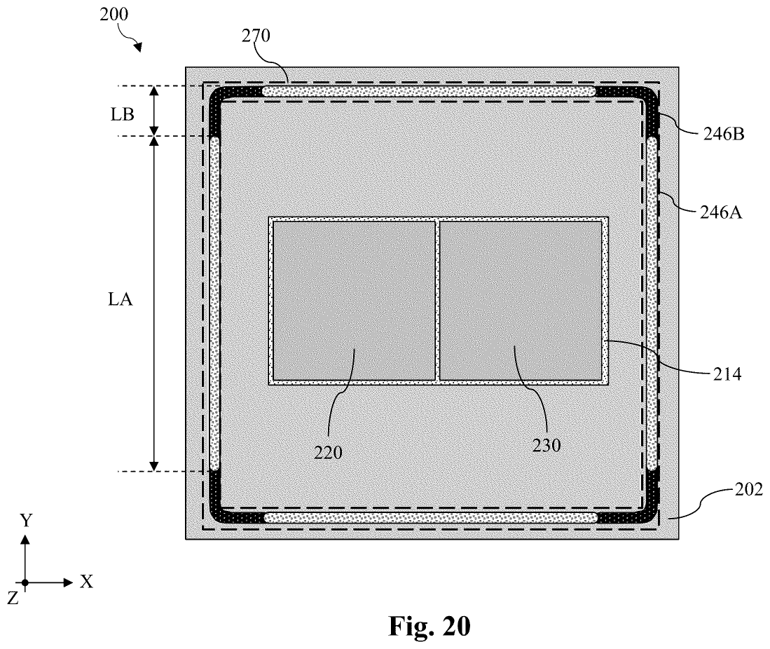

Referring to FIGS. 16 and 19-20, method 400 includes a block 406 where a ring 270 is placed over the package substrate 202 to engage the first adhesive 246A and the second adhesive 246B. In some embodiments, the ring 270 may be formed of a metal or an alloy, such as aluminum (Al), copper (Cu), iron (Fe), nickel (Ni), cobalt (Co), or an alloy thereof. Example alloys may include an aluminum-copper alloy, an iron-nickel alloy, or an iron-nickel-cobalt alloy. Because the ring 270 is formed of a metal or a metal alloy, it may be referred to as a metal ring. At block 406, the ring 270 is placed over the package substrate 202 such that its bottom edges engage the first adhesive 246A and the second adhesive 246B. As representatively shown in FIGS. 19-20, the ring 270 presses the first adhesive 246A and the second adhesive 246B against the package substrate 202 to spread them over a larger area of the package substrate 202.

Referring to FIGS. 16 and 19-20, method 400 includes a block 408 where the first adhesive 246A and the second adhesive 246B are cured. In some embodiments, the first adhesive 246A and the second adhesive 246B are thermally curable. In these embodiments, the WIP structure 200 shown in FIG. 19 may be subject to an anneal process to cure the first adhesive 246A and the second adhesive 246B. In some embodiments, the anneal process for curing the first adhesive 246A and the second adhesive 246B may be between about 130° C. and about 180° C. Reference is made to FIG. 20. The ring 270 may assume a rectangular shape in a top view. Each edge of the ring 270 may a first length LA that engages the first adhesive 246A and a second length LB that engages the second adhesive 246B. In some implementations, the first length LA accounts for between about 70% and about 80% of an edge of the ring 270 while the second length LB accounts for between about 10% and about 15% of an edge of the ring 270.

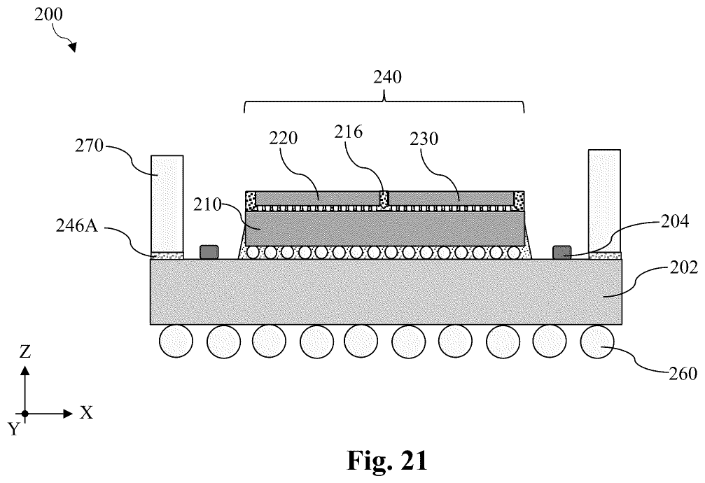

Referring to FIGS. 16 and 21, method 400 includes a block 410 where solder features 260 are formed over a back side of the package substrate 202. Operations at block 410 are substantially similar to those at block 112 of method 100 described above. For that reason, details of operations at block 312 and the solder features 260 are omitted for brevity.

The present disclosure provides many embodiments. In one aspect, the present disclosure provides a package structure. The package structure includes a substrate, a package component bonded to the substrate and including at least one die, a lid disposed over the package component and the substrate, and an interface structure sandwiched between the package component and the lid. The interface structure includes a first thermal interface material disposed at corners of a top surface of the at least one die, and a second thermal interface material disposed over a rest of the top surface of the die. A Young's modulus of the first thermal interface material is smaller than a Young's modulus of the second thermal interface material.

In some embodiments, a thermal conductivity of the second thermal interface material is greater than a thermal conductivity of the first thermal interface material. In some implementations, the first thermal interface material includes a first base material and a filler and the second thermal interface material includes a second base material and the filler. A filler concentration in the second thermal interface material is greater than a filler concentration in the first thermal interface material. In some embodiments, the first base material is different from the second base material. In some embodiments, the first base material includes silicone and the second base material includes resin or epoxy. In some embodiments, the filler includes aluminum oxide, zinc oxide, aluminum nitride, hexagonal boron nitride, copper, silver, aluminum, diamond, graphene, or graphite. In some embodiments, the lid includes a lower edge that is rectangular in shape. In some embodiments, the package structure further includes an adhesive layer sandwiched between the lower edge of the lid and the substrate. The adhesive layer includes a first adhesive disposed at corners of the lower edge of the lid and a second adhesive disposed over a rest of the lower edge of the lid. In some instances, the first adhesive and the second adhesive include an adhesive base material and an adhesive filler. An adhesive filler concentration in the second adhesive is greater than an adhesive filler concentration in the first adhesive. In some embodiments, the adhesive base material includes silicone, nylon, polyetheretherketone (PEEK), epoxy, or resin and the adhesive filler includes silica, zinc oxide, aluminum oxide, silver, or aluminum.

In another aspect, the present disclosure provides a package structure. The package structure includes a substrate, a package component bonded to the substrate and including at least one die, a lid disposed over the package component and the substrate, and including a bottom surface and a lower edge, and an adhesive layer sandwiched between the lower edge and the substrate. The adhesive layer includes a first adhesive disposed at corners of the lower edge of the lid, and a second adhesive disposed a rest of the lower edge of the lid. A Young's modulus of the first adhesive is smaller than a Young's modulus of the second adhesive.

In some embodiments, the lower edge is rectangular in shape and includes four (4) sides. Each of the four (4) sides includes a length. The first adhesive engages between about 20% and about 30% of the length of each of the four (4) sides, and the second adhesive engages between about 70% and about 80% of the length of each of the four (4) sides. In some embodiments, the first adhesive and the second adhesive include an adhesive base material and an adhesive filler and an adhesive filler concentration in the second adhesive is greater than an adhesive filler concentration in the first adhesive. In some embodiments, the adhesive base material includes silicone, nylon, polyetheretherketone (PEEK), epoxy, or resin and the adhesive filler includes silica, zinc oxide, aluminum oxide, silver, or aluminum. In some embodiments, the lid includes aluminum (Al), copper (Cu), iron (Fe), nickel (Ni), cobalt (Co), or an alloy thereof.

In still another aspect, the present disclosure provides a method. The method includes bonding a package component to a front side of a substrate, the package component including a die, dispensing a first thermal interface material and a second thermal interface material over a top surface of the die, placing a lid over the package component and the substrate such that the first thermal interface material and the second thermal interface material are sandwiched between the top surface of the die and a bottom surface of the lid, curing the first thermal interface material and the second thermal interface material, and after the curing, forming solder features over a back side of the substrate.

In some embodiments, the top surface of the die is rectangular in shape. The first thermal interface material is disposed at four (4) corners of the top surface of the die and the second thermal interface material is disposed at a rest of the top surface of the die. In some embodiments, a Young's modulus of the first thermal interface material is smaller than a Young's modulus of the second thermal interface material. In some implementations, the first thermal interface material includes a first base material and a filler and the second thermal interface material includes a second base material and the filler. A filler concentration in the second thermal interface material is greater than a filler concentration in the first thermal interface material. In some instances, the first base material is different from the second base material.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate;
a package component bonded to the substrate and comprising at least one die;
a lid disposed over the package component and the substrate; and
an interface structure sandwiched between the package component and the lid, the interface structure comprising:
a first thermal interface material disposed at corners of a top surface of the at least one die, and
a second thermal interface material disposed over a rest of the top surface of the die,
wherein a Young's modulus of the first thermal interface material is smaller than a Young's modulus of the second thermal interface material.

2. The package structure of claim 1, wherein a thermal conductivity of the second thermal interface material is greater than a thermal conductivity of the first thermal interface material.

3. The package structure of claim 1,
wherein the first thermal interface material comprises a first base material and a filler,
wherein the second thermal interface material comprises a second base material and the filler,
wherein a filler concentration in the second thermal interface material is greater than a filler concentration in the first thermal interface material.

4. The package structure of claim 3, wherein the first base material is different from the second base material.

5. The package structure of claim 3,
wherein the first base material comprises silicone,
wherein the second base material comprises resin or epoxy.

6. The package structure of claim 3, wherein the filler comprises aluminum oxide, zinc oxide, aluminum nitride, hexagonal boron nitride, copper, silver, aluminum, diamond, graphene, or graphite.

7. The package structure of claim 1, wherein the lid includes a lower edge that is rectangular in shape.

8. The package structure of claim 7, further comprising:
an adhesive layer sandwiched between the lower edge of the lid and the substrate,
wherein the adhesive layer comprises:
a first adhesive disposed at corners of the lower edge of the lid, and
a second adhesive disposed over a rest of the lower edge of the lid.

9. The package structure of claim 8,
wherein the first adhesive and the second adhesive comprise an adhesive base material and an adhesive filler,
wherein an adhesive filler concentration in the second adhesive is greater than an adhesive filler concentration in the first adhesive.

10. The package structure of claim 9,
wherein the adhesive base material comprises silicone, nylon, polyetheretherketone (PEEK), epoxy, or resin,
wherein the adhesive filler comprises silica, zinc oxide, aluminum oxide, silver, or aluminum.

11. A package structure, comprising:
a substrate;
a package component bonded to the substrate and comprising at least one die;
a lid disposed over the package component and the substrate, and comprising a bottom surface and a lower edge; and
an adhesive layer sandwiched between the lower edge and the substrate,
wherein the adhesive layer comprises:
a first adhesive disposed at corners of the lower edge of the lid, and
a second adhesive disposed a rest of the lower edge of the lid,
wherein a Young's modulus of the first adhesive is smaller than a Young's modulus of the second adhesive.

12. The package structure of claim 11,
wherein the lower edge is rectangular in shape and comprises four (4) sides,
wherein each of the four (4) sides comprises a length,
wherein the first adhesive engages between about 20% and about 30% of the length of each of the four (4) sides,
wherein the second adhesive engages between about 70% and about 80% of the length of each of the four (4) sides.

13. The package structure of claim 11,
wherein the first adhesive and the second adhesive comprise an adhesive base material and an adhesive filler,
wherein an adhesive filler concentration in the second adhesive is greater than an adhesive filler concentration in the first adhesive.

14. The package structure of claim 13,
wherein the adhesive base material comprises silicone, nylon, polyetheretherketone (PEEK), epoxy, or resin,
wherein the adhesive filler comprises silica, zinc oxide, aluminum oxide, silver, or aluminum.

15. The package structure of claim 11, wherein the lid comprises aluminum (Al), copper (Cu), iron (Fe), nickel (Ni), cobalt (Co), or an alloy thereof.

16. A method, comprising:
bonding a package component to a front side of a substrate, the package component comprising a die;
dispensing a first thermal interface material and a second thermal interface material over a top surface of the die;
placing a lid over the package component and the substrate such that the first thermal interface material and the second thermal interface material are sandwiched between the top surface of the die and a bottom surface of the lid;
curing the first thermal interface material and the second thermal interface material; and
after the curing, forming solder features over a back side of the substrate.

17. The method of claim 16,
wherein the top surface of the die is rectangular in shape,
wherein the first thermal interface material is disposed at four (4) corners of the top surface of the die,
wherein the second thermal interface material is disposed at a rest of the top surface of the die.

18. The method of claim 17, wherein a Young's modulus of the first thermal interface material is smaller than a Young's modulus of the second thermal interface material.

19. The method of claim 16,
wherein the first thermal interface material comprises a first base material and a filler,
wherein the second thermal interface material comprises a second base material and the filler,
wherein a filler concentration in the second thermal interface material is greater than a filler concentration in the first thermal interface material.

20. The method of claim 19, wherein the first base material is different from the second base material.
